(19) United States
(12) Patent Application Publication
(10) Pub. No.: US 2016/0003884 A1
(43) Pub. Date: Jan. 7, 2016

(54) Residual Life Measuring Device for Transformer

(71) Applicant: Chung Yuan Christian University, Zhongli City (TW)

(72) Inventor: Chun-Yao Lee, Fengshan City (TW)

(21) Appl. No.: 14/512,450

(22) Filed: Oct. 12, 2014

(30) Foreign Application Priority Data
Jul. 2, 2014 (TW) 103122804

(51) Int. Cl. G01R 31/02; G01K 13/00; G01N 27/82

(52) U.S. Cl. CPC G01R 31/027; G01N 27/82; G01K 13/00

(57) ABSTRACT

The present invention provides a residual life measuring device for transformer. When using this residual life measuring device to measure a residual life of a transformer, a phase cable of the power transformer is inserted into and passed through a sensing channel of a Hall effect module, and then the phase current of the phase cable is calculated by a process module immediately; meanwhile, the process module is able to further calculate a residual life of the transformer based on the obtained phase current. This residual life measuring device provides a user without having engineering backgrounds to measure the residual life of the power transformer by himself; therefore, according to the measured residual life, the user can determine whether the currently used power transformer needs to be replaced with a new one or not, without completing any complex analysis of the dissolved gas concentration in the insulating oil.

### BACKGROUND OF THE INVENTION

1. Field of the Invention

The present invention relates to the technology filed of transformers, and more particularly, to a novel residual life measuring device for transformer.

2. Description of the Prior Art

With the highly advanced development of industries and modern life, electricity has currently became an indispensable energy and is especially important for technology industry. If the power supply system works abnormally, the science and technology companies will be suffered to heavy losses.

It is well known that transformer is the heart of a power supply system, and the transformer is mainly used for carrying out a voltage conversion function and then provides electricity with a specific voltage to specific users such as factories, office buildings and general houses. A power transformer usually comprises insulation materials such as insulating papers and insulating oil, however, the insulation materials would be decomposed into small molecular gas due to the heat or electric arc produced by the power transformer. Moreover, the small molecular gas would be dissolved in the insulating oil and then causes the increase of the dissolved gas concentration of the insulating oil.

Based on above descriptions, the person skilled in the transformer art is able to know that, the aging of the power transformer can be calculated and predicted by detecting the dissolved gas concentration in the insulating oil of the power transformer; moreover, the transformer engineers can determine whether the power transformer needs to be replaced or maintained according to the measured dissolved gas concentration in the insulating oil. Accordingly, a dissolved gas analysis (DGA) apparatus is then widely used for monitoring the dissolved gas concentration in the insulating oil of the power transformer. The conventional DGA apparatus mainly comprises two application modes. The first application mode is using the DGA apparatus to pump the insulating oil out and then analyze the concentration of gas dissolved in the insulating oil. Differing from the first application mode, the DGA apparatus is integrated into the power transformer in the second application mode, such that a so-called on-line DGA equipment is provided.

According to above description about the first application mode of the DGA apparatus, it is able to know that the power transformer must be stopped before pumping the insulating oil out of the power transformer, so as to ensure the operation security of the analyzing processes. However, because the stop of the power transformer would causes the interruption of the power supply system, the first application mode is obviously not an ideal dissolved gas analyzing method. Although the on-line DGA equipment can synchronously complete the dissolved gas analyzing process with the normal operation of the power transformer, the DGA equipment still cannot be widely used in the commercial power transforms because of its expensive acquisition cost.

Accordingly, in view of the conventional DGA apparatus and DGA equipment still have some shortcomings and drawbacks, the inventor of the present application has made great efforts to make inventive research thereon and eventually provided a residual life measuring device for transformer.

### SUMMARY OF THE INVENTION

The primary objective of the present invention is to provide a residual life measuring device for transformer, which is mainly consisted of a process module and a Hall effect module. When using this residual life measuring device to measure a residual life of a transformer, a phase cable of the external transformer is inserted into and passed through the a sensing channel of the Hall effect module, and then the phase current of the phase cable is calculated by the process module, meanwhile, the process module is able to further calculate a residual life of the external transformer based on the obtained phase current. In this way, the residual life measuring device provides a user without having engineering backgrounds to measure the residual life of the power transformer by himself; therefore, according to the measured residual life, the user can determine whether the currently used power transformer needs to be replaced with a new one or not, without completing any complex analysis of the dissolved gas concentration in the insulating oil.

Accordingly, to achieve the above objectives of the present invention, the inventor proposes a residual life measuring device for transformer, comprising:

a process module, comprising a display unit and a process unit;

a Hall effect module, electrically connected to the process module and having a sensing channel; and

a power supply module, electrically connected to the process module and the Hall effect module;

wherein when a phase cable of an external transformer is inserted into and passes through the sensing channel, the Hall effect module would accordingly generate a hall voltage, such that the process unit is able to calculate and predict a phase current carried by the phase cable according to the hall voltage and a sensitivity parameter of the Hall effect module; therefore, the process module can further calculate a residual life of the external transformer based on the phase current, so as to display the residual life by numeric value through the display unit.

### BRIEF DESCRIPTION OF THE DRAWINGS

The invention as well as a preferred mode of use and advantages thereof will be best understood by referring to the following detailed description of an illustrative embodiment in conjunction with the accompanying drawings, wherein:

FIG. 1 is a block diagram of a residual life measuring device for transformer according to the present invention;

FIG. 2 is a first schematic application diagram of the residual life measuring device;

FIGS. 3A and 3B are second schematic application diagrams of the residual life measuring device; and

FIG. 4 is a flowchart of a residual life measuring method.

### DETAILED DESCRIPTION OF THE PREFERRED EMBODIMENTS

To more clearly describe a residual life measuring device for transformer according to the present invention, embodiments of the present invention will be described in detail with reference to the attached drawings hereinafter.

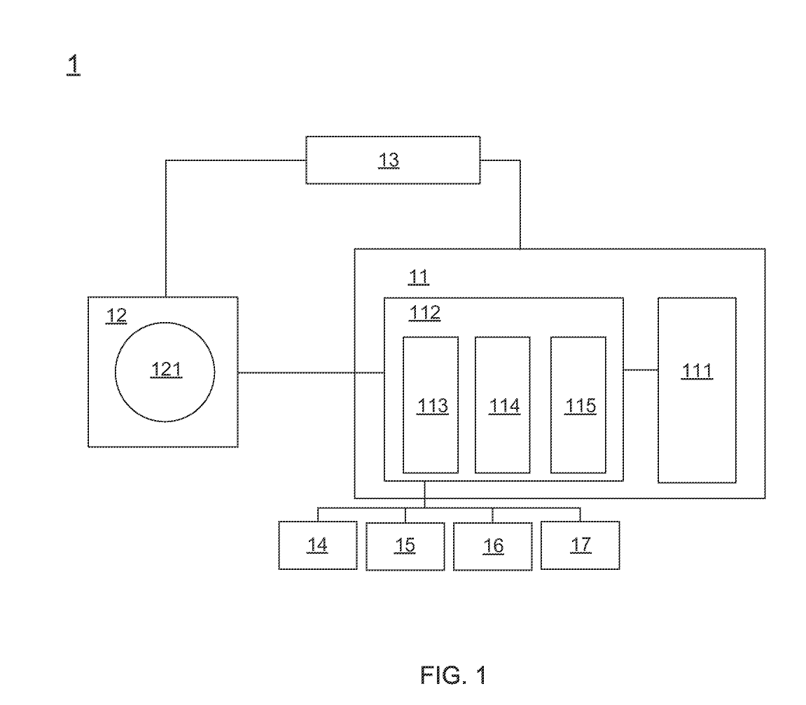

With reference to FIG. 1, there is shown a block diagram of a residual life measuring device for transformer according to the present invention. As shown in FIG. 1, a residual life measuring device 1 for transformer of the present invention comprises a process module 11, a Hall effect module 12 and a power supply module 13. Wherein the process module 11 comprises a display unit 111 and a process unit 112, and the Hall effect module 12 is electrically connected to the process module 11 and has a sensing channel 121, moreover, the power supply module 13, a battery or a power supply in this embodiment, is electrically connected to the process module 11 and the Hall effect module 12 for providing operating power.

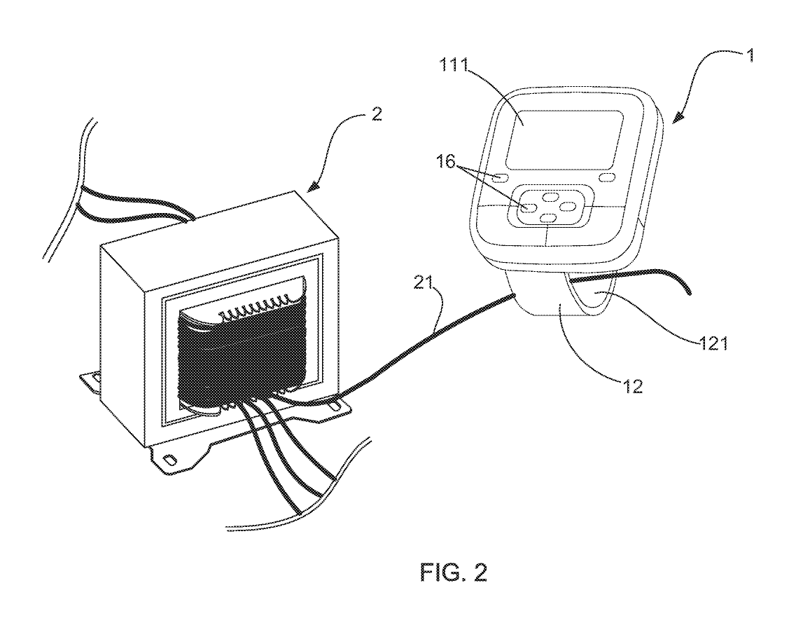

Continuously, please refer to FIG. 1 and FIG. 2, wherein FIG. 2 shows a first schematic application diagram of the residual life measuring device. As shown in FIG. 1 and FIG. 2, the technique feature of the present invention is measuring a phase current of an external transformer 2 through the Hall effect module 12, then calculating and predicting a residual life of the external transformer 2 through the obtained phase current.

When a phase cable 21 of the external transformer 2 is inserted into and passed through the sensing channel 121, the Hall effect module 12 would accordingly generate a hall voltage, and the process unit 112 would be able to calculate and predict the phase current carried by the phase cable 21 according to the hall voltage and a sensitivity parameter of the Hall effect module 12; such that, the process module 11 is able to further calculate the residual life of the external transformer 2 based on the phase current, so as to display the residual life by numeric value through the display unit 111.

In order to calculate values of the phase current and the residual life through the process module 11, a hot spot temperature conversion library 113, an equivalent aging factor conversion library 114, and a passing life calculating library 115 are particularly written into the process unit 112.

Wherein the process unit 112 of the process module 11 applies the hot spot temperature conversion library 113 for calculating a hot spot temperature of the external transformer 2 according to the phase current; then, the process unit 112 can apply the equivalent aging factor conversion library 114 for calculating an equivalent aging factor according to the obtained hot spot temperature; finally, the process unit 112 can further apply the passing life calculating library 115 for calculating a passing life percentage of the external transformer 2 according to the obtained equivalent aging factor, such that the processing unit 112 is able to calculate the residual life according to the passing life percentage.

In order to increase the applied range and the convenience of the present invention, the residual life measuring device 1 further comprises a memory module 14, a connecting module 15, a user interface 16 and a wireless transmission module 17.

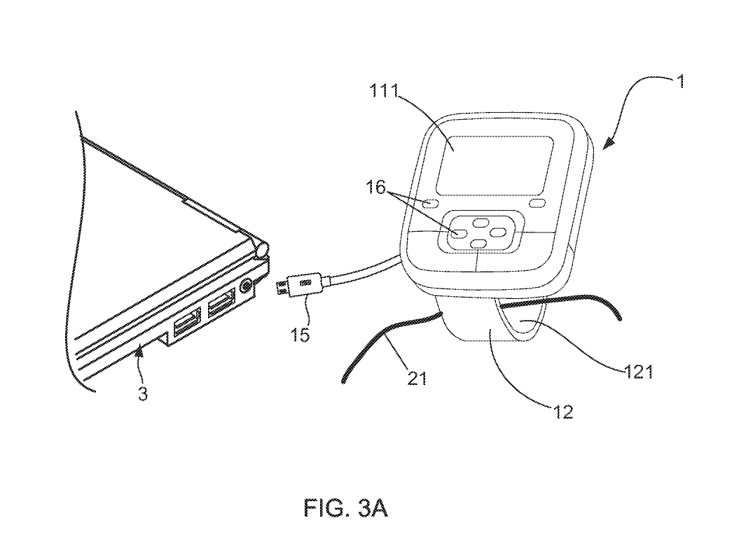

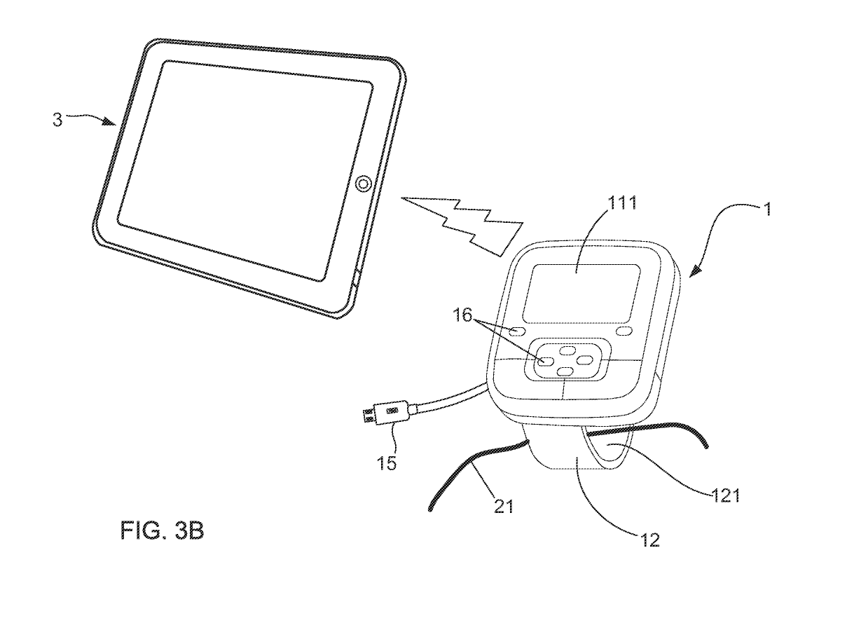

The memory module 14 is coupled to the process unit 112 for storing the data of the phase current and the residual life, as a second schematic application diagram of the residual life measuring device shown in FIG. 3A, the connecting module 15 is coupled to the process unit 112, such that the process unit 112 can be electrically connected to an external electronic device 3 through the connecting module 15, so as to transmit the data of the phase current and the residual life, stored in the memory module 14, to the external electronic device 3; wherein, the memory module 14 of the present invention can be a memory card or a hard disk, and the connecting module 15 can be a USB connector, a Mini USB connector, or a Micro USB connector.

In addition, the user interface 16 is coupled to the processing unit 112 so as to provide users to operate the residual life measuring device and/or set the sensitivity parameter of the Hall effect module 12 and a reference phase current for calculating; such that users can measure the phase current and the residual life of the external transformer 2 after the presetting processes of the sensitivity parameter and the reference phase current are finished.

Besides, based on the wild application of the wireless transmission technologies, the present invention provides the wireless transmission module 17, which is coupled to the process unit 112. As a second schematic application diagram of the residual life measuring device shown in FIG. 3B, the process unit 112 is able to selectively transmit the data of the phase current and the residual life to the external electronic device 3 (a notebook computers, a tablet computers, or a smart phones) through the wireless transmission module 17.

On the other hand, the process unit 112 can also transmit the data of the phase current and the residual life to a remote monitoring system through the wireless transmission module 17, and recording and monitoring the phase current and the residual life of transformers. The wireless transmission module 17 of the present invention can be selected from the group consisting of: Wi-Fi transmission module, RFID transmission module, Bluetooth transmission module, IR transmission module, Zigbee transmission module, 3G communication module, and 4G communication module.

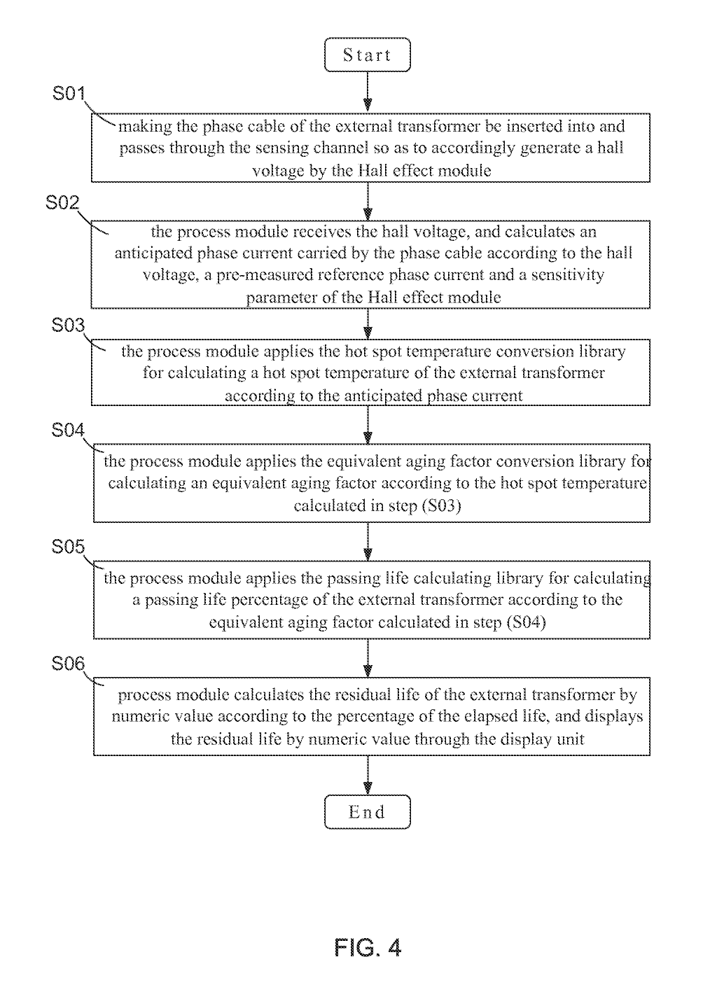

Through above descriptions, constituting elements of the related technology features of the residual life measuring device for transformer of the present invention have been clearly and completely introduced; next, the estimation method of the residual life measuring device will be described in follows. Please refer to FIG. 4, there is shown a flowchart of a residual life measuring method according to the residual life measuring device. As shown in FIG. 4, this residual life measuring method includes 6 steps:

Firstly, the method proceeds to step (S01), making the phase cable 21 of the external transformer 2 be inserted into and passes through the sensing channel 121 so as to accordingly generate a hall voltage by the Hall effect module 12. Then, proceeds to step (S02), the process module 11 receives the hall voltage, and calculates an anticipated phase current carried by the phase cable 21 according to the hall voltage, a pre-measured reference phase current and a sensitivity parameter of the Hall effect module 12. After finished step (S02), step (S03) can be executed, the process module 11 applies the hot spot temperature conversion library 113 for calculating a hot spot temperature of the external transformer 2 according to the anticipated phase current.

The hot spot temperature conversion library 113 comprises a hot spot temperature conversion formula of Θ_{H}=Θ_{A}+ΔΘ_{TO}+ΔΘ_{H}, wherein Θ_{H} represents the hot spot temperature, Θ_{A} represents an ambient temperature of the external transformer 2, ΔΘ_{TO} represents a top-oil rise over ambient temperature of the external transformer 2, and ΔΘ_{H} represents a winding hottest-spot rise over top-oil temperature of the external transformer 2. Furthermore, the ΔΘ_{TO} can be calculated through the following formula (1):

$$Δ {Θ}_{TO} = ( Δ {Θ}_{TO , U} - Δ {Θ}_{TO , i} ) ( 1 - {exp}^{\frac{- t}{{}^{τ} TO}} ) + Δ {Θ}_{TO , i} \qquad ( 1 )$$

According to the above presented formula (1), ΔΘ_{TO,U} and ΔΘ_{TO,i} are ultimate top-oil rise over ambient temperature and initial top-oil rise over ambient temperature, respectively. Besides, τ_{TO} is oil time constant and t is duration of load. Moreover, the ΔΘ_{TO,U} and ΔΘ_{TO,I} in formula (1) can be calculated through the following formula (2) and formula (3):

$$\begin{matrix}Δ {Θ}_{TO , U} = Δ {{Θ}_{TO , R} ( \frac{{k}_{U}^{2} R + 1}{R + 1} )}^{n} & ( 2 ) \\ Δ {Θ}_{TO , i} = Δ {{Θ}_{TO , R} ( \frac{{k}_{i}^{2} R + 1}{R + 1} )}^{n} & ( 3 )\end{matrix}$$

In the formula (2) and formula (3), kᵢ is ratio of initial load, k_{U} is ratio of ultimate load, R is ratio of rated load loss to no-load loss, ΔΘ_{TO,R} is top-oil rise over ambient temperature at rated load, and n is empirically derived exponent of the ΔΘ_{TO}. Therefore, when the formula (2) and formula (3) are applied into the formula (1), the ΔΘ_{TO}, representing the top-oil rise over ambient temperature of the external transformer 2, can be recognized as a function of the ratio of initial load kᵢ and the ratio of ultimate load k_{U}

In addition, the ΔΘ_{H}, representing the winding hottest-spot rise over top-oil temperature of the external transformer 2, can be calculated through the following formula (4):

$$Δ {Θ}_{H} = ( Δ {Θ}_{H , U} - Δ {Θ}_{H , i} ) ( 1 - {exp}^{\frac{- t}{{}^{τ} W}} ) + Δ {Θ}_{H , i} \qquad ( 4 )$$

According to the above presented formula (4), ΔΘ_{H,U} and ΔΘ_{H,i} are ultimate winding hottest-spot rise over top-oil temperature and initial winding hottest-spot rise over top-oil temperature, respectively. Besides, τ_{W} is winding time constant, wherein the ΔΘ_{H, U} and ΔΘ_{H,I} can be calculated through the following formula (5) and formula (6):

ΔΘ_{H,U}=ΔΘ_{H,R}×k_{U}^{2m} (5)

ΔΘ_{H,i}=ΔΘ_{H,R}×kᵢ^{2m} (6)

In the formula (5) and formula (6), ΔΘ_{H,R} is winding hottest-spot rise over top-oil temperature at rated load, and m is empirically derived exponent of the ΔΘ_{H}. Therefore, when the formula (5) and formula (6) are applied into the formula (4), the ΔΘ_{H}, representing the winding hottest-spot rise over top-oil temperature of the external transformer 2, can also be recognized as a function of the ratio of initial load kᵢ and the ratio of ultimate load k_{U}.

Furthermore, when the ratio of initial load kᵢ and the ratio of ultimate load k_{U} are defined as k, representing a ratio of load to be carried to 100% rating, the hot spot temperature conversion formula of Θ_{H}=Θ_{A}+ΔΘ_{TO}+ΔΘ_{H} can be transformed into the following formula (7) through the formula (1) and formula (4) with k:

$${Θ}_{H} = {Θ}_{A} + Δ {Θ}_{TO , R} \times {( \frac{{k}^{2} R + 1}{R + 1} )}^{n} + Δ {Θ}_{H , R} \times {k}^{2 m} \qquad ( 7 )$$

According to the above presented formula (7), because of the unchanged output power of the external transformer 2, the ratio of load to be carried to 100% rating of k can be calculated through the obtained phase current so as to calculate the hot spot temperature Θ_{H} of the external transformer 2.

After calculated the hot spot temperature Θ_{H}, step (S04) can be executed, the process module 11 applies the equivalent aging factor conversion library 114 for calculating an equivalent aging factor according to the hot spot temperature Θ_{H} calculated in step (S03).

Wherein the equivalent aging factor conversion library 114 comprises an equivalent aging factor conversion formula:

F_{EQA}=[Σₙ₌₁^{N} F_{AA,n}Δtₙ]/[Σₙ₌₁^{N} Δtₙ]

According to the equivalent aging factor conversion formula, F_{EQA} is an equivalent aging factor, n is a time interval index, N is a time interval total number, and Δtₙ represents a time interval, moreover, F_{AA,n} is an accelerated aging factor, which can be calculated by the following formula (8):

$${F}_{AA} = EXP ( \frac{15 , 000}{383} - \frac{15 , 000}{{Θ}_{H} + 273} ) \qquad ( 8 )$$

Therefore, the equivalent aging factor F_{EQA} of the external transformer 2 can be calculated according to the obtained phase current as long as the formula (7) is applied into the formula (8), then formula (8) is able to be applied into the equivalent aging factor conversion formula.

Moreover, after the equivalent aging factor F_{EQA} is calculated, step (S05) can be executed, the process module 11 applies the passing life calculating library 115 for calculating a passing life percentage of the external transformer 2 according to the equivalent aging factor F_{EQA} calculated in step (S04).

Furthermore, when the equivalent aging factor F_{EQA} is multiplied with the duration of load t of the external transformer 2, and compared the product with the normal insulation life of the external transformer 2, the percentage of the elapsed life can be calculated and present as the following formula:

$$elapsed life ( \% ) = \frac{{F}_{EQA} \times t \times 100}{Normal insulation life} .$$

Finally, proceeds to step (S06), process module 11 calculates the residual life of the external transformer 2 by numeric value according to the percentage of the elapsed life, and displays the residual life by numeric value through the display unit 111.

Thus, through above descriptions, the technology features and the residual life measuring method of the present invention have been clearly and completely introduced; in summary, the present invention has the following advantages:

1. Different from conventional DGA apparatus, the residual life measuring device for transformer of the present invention merely comprising a process module and a Hall effect module, such that the advantages of the residual life measuring device are simpler structure, smaller size, lower manufacturing cost, higher applicability, and lower price than a conventional DGA apparatus.

2. In addition, the usage of the residual life measuring device is very simple, when using this residual life measuring device to measure a residual life of a power transformer, a phase cable of the power transformer is inserted into and passed through a sensing channel of a Hall effect module, and then the phase current of the phase cable is calculated by a process module immediately; meanwhile, the process module is able to further calculate a residual life of the transformer based on the obtained phase current. This residual life measuring device provides a user without having engineering backgrounds to measure the residual life of the power transformer by himself; therefore, according to the measured residual life, the user can determine whether the currently used power transformer needs to be replaced with a new one or not, without completing any complex analysis of the dissolved gas concentration in the insulating oil.

What is claimed is:

1. A residual life measuring device for transformer, comprising:
a process module, comprising a display unit and a process unit;
a Hall effect module, being electrically connected to the process module and having a sensing channel; and
a power supply module, being electrically connected to the process module and the Hall effect module;
wherein when a phase cable of an external transformer is inserted into and passes through the sensing channel, the Hall effect module would accordingly generate a hall voltage, such that the process unit is able to calculate and predict a phase current carried by the phase cable according to the hall voltage and a sensitivity parameter of the Hall effect module; therefore, the process module can further calculate a residual life of the external transformer based on the phase current, so as to display the residual life by numeric value through the display unit.

2. The residual life measuring device of claim 1, wherein the processing unit comprises:
a hot spot temperature conversion library for calculating a hot spot temperature of the external transformer according to the phase current;
an equivalent aging factor conversion library for calculating an equivalent aging factor according to the hot spot temperature; and
a passing life calculating library, for calculating a passing life percentage of the external transformer according to the equivalent aging factor, such that the processing unit is able to calculate the residual life according to the passing life percentage.

3. The residual life measuring device of claim 2 further comprises:
a memory module, being coupled to the process unit for storing the data of the phase current and the residual life;
a connecting module, being coupled to the process unit, such that the process unit can be electrically connected to an external electronic device through the connecting module, so as to transfer the data of the phase current and the residual life stored in the memory module to the external electronic device; and
a user interface, being coupled to the processing unit so as to provide users to operate the residual life measuring device and/or set the sensitivity parameter of the Hall effect module.

4. The residual life measuring device of claim 2, wherein the hot spot temperature conversion library comprises a hot spot temperature conversion formula of Θ_{H}=Θ_{A}+ΔΘ_{TO}+ΔΘ_{H}, wherein Θ_{H} represents the hot spot temperature, Θ_{A} represents an ambient temperature of the external transformer, ΔΘ_{TO} represents a top-oil rise over ambient temperature of the external transformer, and ΔΘ_{H} represents a winding hottest-spot rise over top-oil temperature of the external transformer.

5. The residual life measuring device of claim 4, wherein the equivalent aging factor conversion library comprises an equivalent aging factor conversion formula of F_{EQA}=[Σₙ₌₁^{N} F_{AA,n}Δtₙ]/[Σₙ₌₁^{N} Δtₙ], wherein the F_{EQA} is an equivalent aging factor, F_{AA,n} is an accelerated aging factor, n is a time interval index, N is a time interval total number, and Δtₙ represents a time interval.

6. The residual life measuring device of claim 3, wherein the memory module is selected from the group consisting of: memory card and hard disk.

7. The residual life measuring device of claim 3, wherein the connecting module is selected from the group consisting of: USB connector, Mini USB connector, and Micro USB connector.

8. The residual life measuring device of claim 1, wherein the power supply module is selected from the group consisting of: battery and power supply.

9. The residual life measuring device of claim 2 further comprises a wireless transmission module, being coupled to the process unit, such that the process unit is able to transfer the data of the phase current and the residual life to the external electronic device through the wireless transmission module.

10. The residual life measuring device of claim 9, wherein the wireless transmission module is selected from the group consisting of: Wi-Fi transmission module, RFID transmission module, Bluetooth transmission module, IR transmission module, Zigbee transmission module, 3G communication module, and 4G communication module.
